(19) United States
(12) Patent Application Publication
(10) Pub. No.: US 2006/0141721 A1
(43) Pub. Date: Jun. 29, 2006

(54) Semiconductor transistor device and method for manufacturing the same

(75) Inventor: Young Seong Lee, Anyang city (KR)

Correspondence Address: MCKENNA LONG & ALDRIDGE LLP, 1900 K STREET, NW, WASHINGTON, DC, 20006, US

(73) Assignee: DongbuAnam Semiconductor Inc., Seoul (KR)

(21) Appl. No.: 11/319,229

(22) Filed: Dec. 28, 2005

(30) Foreign Application Priority Data
Dec. 29, 2004 (KR) P 2004-0115759

(51) Int. Cl. H01L 21/336

(52) U.S. Cl. 438/299

(57) ABSTRACT

A semiconductor transistor device and a method for manufacturing the same are provided. The method includes forming a silicon epitaxial layer having a predetermined thickness in source and drain diffusion regions of a silicon semiconductor substrate and forming a source and drain junction by ion implantation and rapid annealing in the silicon semiconductor substrate in which the silicon epitaxial layer is formed. The semiconductor transistor device includes a silicon epitaxial layer formed to have a predetermined thickness in source and drain diffusion regions of a silicon semiconductor substrate. Thus, since a salicide layer is used without increase of leakage current, the transistor device having low power and high performance can be manufactured.

This application claims the benefit of Korean Patent Application No. 10-2004-0115759, filed on Dec. 29, 2004, which is hereby incorporated by reference for all purposes as if fully set forth herein.

### BACKGROUND OF THE INVENTION

1. Field of the Invention

The present invention relates to semiconductor transistor devices, and more particularly, to a semiconductor transistor device and a method for manufacturing the same in which a silicon epitaxial layer is formed in source and drain diffusion regions.

2. Discussion on the Related Art

For application of a semiconductor device to the field of portable multimedia, development of a low-power device that minimizes power consumption is essential. To reduce power consumption in a semiconductor device, it is important to minimize leakage current, which has various sources and occurs along a variety of paths. Low-power devices aim to reduce such leakage current, including transistor off-leakage and junction leakage, which can be improved by controlling the profile of a source and drain ion implantation layer. Particularly, gate-induced drain leakage and salicide induced leakage, which are associated characteristics caused by channel overlap, depend on the depth of the profile, and such leakage current should be minimized.

To minimize the leakage current of the low power device, a shallow junction has been suggested. If an ion implantation energy is controlled during source and drain ion implantation to minimize the depth of the junction, channel overlap is reduced so that transistor off-leakage can be reduced and a degradation of a gate oxide due to hot carriers can be avoided. The most effective application of this method however is limited to devices having no salicide layer.

FIG. 1 shows a related art semiconductor transistor device without a salicide layer. A gate oxide film 24 and a polysilicon 22 are deposited on a semiconductor substrate 10 of silicon in which a shallow-trench isolation region 10a is formed. The gate oxide film 24 and the polysilicon 22 are patterned to form a gate electrode 20. Next, a lightly doped drain region 12 is formed by ion implantation using low energy. A rapid annealing process is then carried out to activate impurity ions. Then, a spacer of a buffer oxide film 24 and a nitride film 26 are formed at sidewalls of the gate electrode 20. Source and drain diffusion regions 14 are formed by heavily doped ion implantation using the gate electrode 20 and the spacer 26 as a mask, after which salicide layers 16 and 28 are formed to reduce surface resistance.

If, however, the salicide layer 16 is formed on the source and drain diffusion regions 14 formed by a shallow junction as shown in FIG. 1, a depth ratio between the salicide layer and the junction is reduced. Thus, a defect occurring in the boundary between the salicide layer and the junction is easily activated to increase leakage current in the junction. Therefore, application of such technology is limited to lower performance devices. To obtain high performance in addition to low power, a salicide layer is required. Therefore, technology for forming a shallow junction suitable for the salicide layer is required.

### SUMMARY OF THE INVENTION

Accordingly, the present invention is directed to a semiconductor transistor device and a method for manufacturing the same that substantially obviates one or more problems to limitations and disadvantages of the related art.

An advantage of the present invention is to provide a semiconductor transistor device and a method for manufacturing the same in which leakage current is effectively prevented from occurring in a shallow junction in which a salicide layer is formed.

Another advantage of the present invention is to provide a semiconductor transistor device and a method for manufacturing the same in which a depth of a shallow junction is simply controlled to obtain low power and high performance.

Additional features and advantages of the invention will be set forth in the description which follows, and in part will be apparent from the description, or may be learned by practice of the invention. The objectives and other advantages of the invention will be realized and attained by the structure and method particularly pointed out in the written description and claims hereof as well as the appended drawings.

To achieve these and other advantages and in accordance with the purpose of the invention, as embodied and broadly described, there is provided a method for manufacturing a semiconductor transistor device, the method comprising forming a silicon epitaxial layer having a predetermined thickness in source and drain diffusion regions of a silicon semiconductor substrate provided with a gate electrode and a spacer; and forming a source and drain junction by ion implantation and rapid annealing in the silicon semiconductor substrate in which the silicon epitaxial layer is formed.

In another aspect of the present invention, a semiconductor transistor device manufactured by the above method includes a silicon semiconductor substrate provided with a gate electrode and a spacer, and a silicon epitaxial layer formed to have a predetermined thickness in source and drain diffusion regions of the silicon semiconductor substrate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principle of the invention. In the drawings:

FIG. 1 is a sectional view of a related art semiconductor transistor device;

FIG. 2 is a sectional view of a semiconductor transistor device in which a silicon epitaxial layer is formed by a method according to the present invention; and

FIG. 3 is a sectional view illustrating a semiconductor transistor device in which salicide layers are formed on a gate electrode and source and drain diffusion regions by a method according to the present invention.

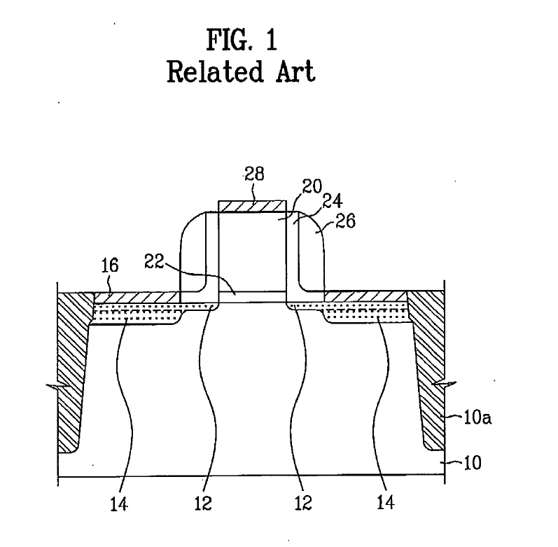

### DETAILED DESCRIPTION OF THE INVENTION

Reference will now be made in detail to embodiments of the present invention, examples of which are illustrated in the accompanying drawings. Wherever possible, like reference designations will be used throughout the drawings to refer to the same or similar parts.

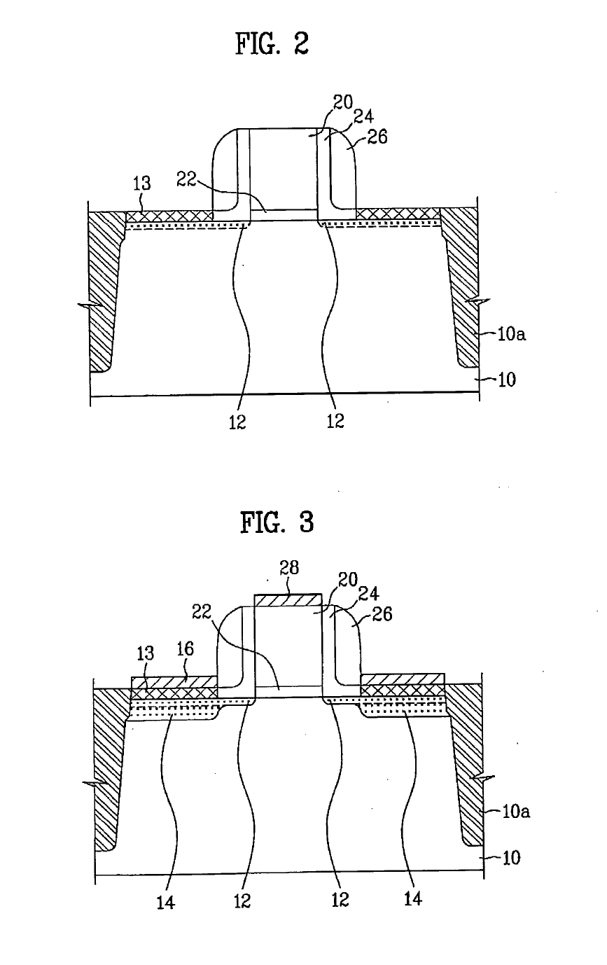

Referring to FIGS. 2 and 3, an active region 22, a shallow-trench isolation region 10a, a polysilicon gate 20, a gate spacer 26 and a lightly doped drain region 12 are formed in a semiconductor substrate 10 of silicon. A buffer oxide film 24 may be interposed between the polysilicon gate 20 and the gate spacer 26 to prevent the polysilicon gate 20 from being damaged by the gate spacer 26 if the gate spacer 26 is a nitride film. The oxide film on the semiconductor substrate 10 provided with the gate spacer 26 is removed by a wet etching process using HF solution. A silicon epitaxial layer 13 is then grown by an epitaxial growth method. The epitaxial growth method is used to selectively grow the silicon layer having orientation on the silicon substrate. Since the silicon epitaxial layer 13 has a matching relation with the silicon substrate 10, a defect on the boundary between the silicon epitaxial layer 13 and the silicon substrate 10 is suppressed.

The silicon epitaxial layer 13 may have has a thickness less than that of the polysilicon gate by 30%. This is to prevent a salicide bridge from being formed on the gate 20 and the silicon epitaxial layer 13 during a later salicide process and sufficiently enables coverage of a nitride film to be deposited later.

A source and drain junction 14 is formed by ion implantation and rapid annealing processes on the silicon substrate 10 in which the silicon epitaxial layer 13 is formed. To control the depth of the junction, implantation energy is set considering transmittance of ions to the silicon epitaxial layer 13 grown on the substrate 10. That is, the profile depth of the junction in the silicon substrate 10 is approximated to a value obtained by subtracting the thickness of the silicon epitaxial layer 13 from the whole depth. Therefore, the shallow junction can be obtained by controlling only the thickness of the silicon epitaxial layer 13 without controlling the ion implantation energy. There is a practical limit to controlling the junction depth by controlling the ion implantation energy due to limits in varying the ion implantation energy. In the present invention, it is possible to easily control the junction depth without controlling ion implantation energy.

After the source and drain junction 14 is formed, a salicide process is carried out using a salicide metal such as Co or Ti. A salicide reaction occurs on a surface of the gate electrode 20 and a surface of the silicon epitaxial layer 13. Thus, salicide layers 16 and 28 are respectively formed on the surfaces of the gate electrode 20 and the silicon epitaxial layer 13.

If the silicon epitaxial layer 13 is additionally formed on the source and drain diffusion regions, the distance from the salicide layer to the junction boundary equals the thickness of the silicon epitaxial layer 13, even if the source and drain junction is formed to obtain a shallow junction. In other words, in spite of the formation of a shallow junction, a predetermined distance from the salicide layer 16 to the junction boundary can be maintained. Therefore, it is possible to effectively avoid leakage current through the junction.

After the salicide layers 16 and 28 are formed, the semiconductor transistor device is completed by conventional processing. Lightly doped drain regions 12 are shown.

Since the silicon epitaxial layer is formed on the source and drain diffusion regions and the salicide layer is formed on the silicon epitaxial layer, a depth ratio between the salicide layer and the junction can uniformly be maintained. Therefore, in case where the source and drain diffusion regions are formed by the shallow junction, it is possible to improve junction leakage due to salicide. Also, the related art method for forming a shallow junction requires the depth control based on sophisticated ion implantation but the present invention facilitates control of the junction depth without a separate control technique by controlling only the thickness of the silicon epitaxial layer.

Since the junction depth of the source and drain regions is minimized, channel overlap can be reduced. This improves characteristics of hot carrier and gate-induced drain leakage caused by strong electric field of the overlap region. Furthermore, since the salicide layer is used without increase of leakage current, the transistor device having low power and high performance can be manufactured.

It will be apparent to those skilled in the art that various modifications and variation can be made in the present invention without departing from the spirit or scope of the invention. Thus, it is intended that the present invention cover the modifications and variation of this invention provided they come within the scope of the appended claims and their equivalents.

What is claimed is:

1. A method for manufacturing a semiconductor transistor device, comprising:
forming a silicon epitaxial layer having a predetermined thickness in source and drain diffusion regions of a silicon semiconductor substrate; and
forming a source and drain junction by ion implantation and rapid annealing in the silicon semiconductor substrate in which the silicon epitaxial layer is formed.

2. The method of claim 1, wherein the silicon epitaxial layer has a thickness that is 30% less than that of the gate electrode.

3. The method of claim 1, further comprising forming salicide layers on the gate electrode and the silicon epitaxial layer after forming the source and drain junction.

4. The method of claim 1, wherein the silicon semiconductor substrate is provided with a gate electrode and a spacer.

5. A semiconductor transistor device, comprising:
a silicon semiconductor substrate provided with a gate electrode and a spacer; and
a silicon epitaxial layer formed to have a predetermined thickness in source and drain diffusion regions of the silicon semiconductor substrate.

6. The semiconductor transistor device of claim 5, further comprising:
a source and drain junction formed by ion implantation and rapid annealing in the silicon semiconductor substrate in which the silicon epitaxial layer is formed,
wherein the silicon epitaxial layer is formed on source and drain diffusion regions of the silicon semiconductor substrate.

7. The semiconductor transistor device of claim 5, wherein the silicon epitaxial layer has a thickness that is 30% less than that of the gate electrode.
